(19) United States
(12) Patent Application Publication
(10) Pub. No.: US 2008/0145789 A1
(43) Pub. Date: Jun. 19, 2008

(54) Method of making lithographic printing plates

(76) Inventor: Elizabeth Knight, Lafayette, CO (US)

Correspondence Address: Andrew J. Anderson;Patent Legal Staff, Eastman Kodak Company, 343 State Street, Rochester, NY, 14650-2201, US

(21) Appl. No.: 11/549,160

(22) Filed: Oct. 13, 2006

(51) Int. Cl. G03F 7/00

(52) U.S. Cl. 430/300

(57) ABSTRACT

A negative-working imageable element having an imageable layer on a substrate can be used to form an imaged element by imagewise exposing it to form exposed and non-exposed regions in the imageable layer. The imageable element also has a water-soluble topcoat disposed on the imageable layer. With or without a preheat step, the water-soluble topcoat is at least partially removed with water or an aqueous solution that incompletely or not at all removes the non-exposed regions of the imageable layer. The element is then mounted in a printing press and contacted with a fountain solution, a lithographic printing ink, or a combination of a fountain solution and a lithographic printing ink, thereby removing non-exposed regions of the imageable layer at the beginning of the printing operation.

### FIELD OF THE INVENTION

This invention relates to a method of imaging and on-press processing of negative-working imageable elements to provide lithographic printing plates. The invention also relates to methods of using the imaged elements for printing.

### BACKGROUND OF THE INVENTION

Radiation-sensitive compositions are routinely used in the preparation of imageable materials including lithographic printing plate precursors. Such compositions generally include a radiation-sensitive component, a radically polymerizable component, an initiator system, and a binder, each of which has been the focus of research to provide various improvements in physical properties, imaging performance, and image characteristics.

Recent developments in the field of printing plate precursors concern the use of radiation-sensitive compositions that can be imaged by means of lasers or laser diodes, and more particularly, that can be imaged and/or developed on-press. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of from about 700 nm, and thus the radiation-sensitive compositions are required to be sensitive in the near-infrared or infrared region of the electromagnetic spectrum. However, other useful radiation-sensitive compositions are designed for imaging with ultraviolet or visible radiation.

There are two possible ways of using radiation-sensitive compositions for the preparation of printing plates. For negative-working printing plates, exposed regions in the radiation-sensitive compositions are hardened and non-exposed regions are washed off during development. For positive-working printing plates, the exposed regions are dissolved in a developer and the non-exposed regions become an image.

Various negative-working radiation compositions and imageable elements are known in the art. Some of these compositions and elements are described for example in U.S. Pat. No. 6,569,603 (Furukawa), U.S. Pat. No. 6,309,792 (Hauck et al.), U.S. Pat. No. 6,582,882 (Pappas et al.), U.S. Pat. No. 6,893,797 (Munnelly et al.), and U.S. Pat. No. 6,787,281 (Tao et al.), U.S. Patent Application Publication 2003/0118939 (West et al.), and EP 1,079,276A1 (Lifka et al.), and EP 1,449,650A1 (Goto).

Imaged elements typically require processing in a solvent-based or aqueous alkaline developer to convert them to lithographic printing plates. While such developers are very effective for this use, there are a number of reasons why workers in the industry have looked for methods to avoid them. For example, U.S. Patent Application Publication 2005/0263021 (Mitsumoto et al.) describes the use of water or a gumming solution to develop imaged elements at a temperature that is higher than the T_{g} of the polymeric binder in the imageable layer of the element. Similarly, U.S. Patent Application Publication 2005/0266349 (Van Damme et al.) describes an off-press development step using a gumming solution.

“On-press” development technology has become more prominent in recent years to avoid the use of traditional developers. On-press developable imageable elements have been designed for this purpose as described, for example in U.S. Pat. No. 6,582,882 (Hayashi et al.), U.S. Pat. No. 6,899,994 (Huang et al.), and U.S. Pat. No. 7,005,234 (Hoshi et al.) and U.S. Patent Published Applications 2005/003285 (Hayashi et al.) and 2006/0057492 (Kunita et al.). Such elements can be directly mounted on a press after imaging, and developed through contact with a lithographic printing ink, fountain solution, or both. Thus, a separate development step after imaging using a traditional developer is avoided. On-press imaging, in which the imageable element is both imaged and developed on-press, eliminates the need to mount the element in a separate imaging device.

### Problem to be Solved

Negative-working imageable elements are often prepared with water-soluble protective topcoats that serve as oxygen barriers. After imaging, the plate precursor must generally go through a pre-rinse to remove the protective topcoat, a developer to remove the non-imaged imageable layer, and finally a finishing solution to protect the newly exposed substrate. There is a need for a method of providing a lithographic printing plate where the simplest solutions are used to remove the protective topcoats without the need to completely develop the imageable layer, thus removing the steps of using a developer and a finishing solution. There is also a need for an on-press method of providing lithographic printing plates where low residue is generated in the printing press.

### SUMMARY OF THE INVENTION

The present invention provides a method of making an imaged element comprising:

A) imagewise exposing an imageable element comprising a hydrophilic support having thereon a negative-working imageable layer to form exposed and non-exposed regions in the imageable layer,

the imageable element also comprising a water-soluble topcoat disposed on the imageable layer,

B) with or without a post exposure bake step, pre-rinsing the imagewise exposed element with water or an aqueous solution to at least partially remove the water-soluble topcoat on the imagewise exposed element and incompletely or not at all, to remove the non-exposed regions of the imageable layer, and

C) after mounting it in a printing press, contacting the imagewise exposed imageable element with a fountain solution, a lithographic printing ink, or a combination of a fountain solution and a lithographic printing ink, thereby removing non-exposed regions of the imageable layer.

In preferred embodiments, the invention provides a method of making an imaged element comprising:

A) imagewise exposing an imageable element comprising a hydrophilic support having thereon a negative-working imageable layer to form exposed and non-exposed regions in the imageable layer, the imagewise exposing being carried out using imaging radiation having a λₘₐₓ of from about 300 to about 450 nm,

the imageable layer comprising a radiation absorbing compound that is a 2,4,5-triaryloxazole derivative, a free radically polymerizable component, an initiator composition that comprises a hexaarylbiimidazole, and a polymeric binder that is derived from all of (meth)acrylonitrile, styrene, and poly(ethylene glycol) methyl ether (meth)acrylate, the polymeric binder being present at least partially in the form of discrete particles,

the imageable element also comprising a water-soluble topcoat comprising poly(vinyl alcohol) that is disposed on the imageable layer,

B) with or without a post exposure bake step, pre-rinsing the imagewise exposed element with water to remove substantially all of the water-soluble topcoat,

B′) mounting the imagewise exposed imageable element in a printing press, and

C) contacting the mounted imagewise exposed imageable element with a fountain solution and then a lithographic printing ink, thereby removing the non-exposed regions of the imageable layer.

This invention also provides a method of making an imaged element comprising:

A) imagewise exposing an imageable element comprising a hydrophilic support having thereon a negative-working imageable layer to form exposed and non-exposed regions in the imageable layer,

the imageable element also comprising a water-soluble topcoat disposed on the imageable layer,

B) with or without a post exposure bake step, pre-rinsing the imagewise exposed element with water or an aqueous solution to at least partially remove the water-soluble topcoat on the imagewise exposed element and incompletely or not at all, to remove the non-exposed regions of the imageable layer, and

C) after mounting it in a printing press, contacting the imagewise exposed imageable element with a fountain solution, a lithographic printing ink, or a combination of a fountain solution and a lithographic printing ink, thereby removing non-exposed regions of the imageable layer, and

D) simultaneously with or subsequently to step C, using the mounted imagewise exposed imageable element to provide a printed image.

I have found that negative-working imageable elements having a water-soluble topcoat can be imaged and developed particularly on-press using combinations of lithographic printing inks and fountains solutions. The topcoat can be at least partially and preferably completely removed after imaging and before development using water or a simple aqueous solution in a pre-rinse step. The non-exposed regions of the imaged layer are incompletely or not at all removed during the pre-rinse step.

This method has the advantages of providing topcoat removal before development without the need for additional development and finishing steps. In addition, if portions of the non-exposed regions of the imaged layer are removed during the pre-rinse step, less residue is generated in the printing press thereby reducing maintenance and disposal costs. For the preferred embodiments where the imageable element is sensitive to “violet” irradiation, there is also the advantage that the imaging device is generally less costly than longer wavelength devices.

### DETAILED DESCRIPTION OF THE INVENTION

### Definitions

Unless the context indicates otherwise, when used herein, the term “method” is meant to be a reference to embodiments of the present invention.

In addition, unless the context indicates otherwise, the various components described herein such as “radically polymerizable component”, “radiation absorbing compound”, “polymeric binder”, “initiator”, “co-initiator”, and similar terms also refer to mixtures of such components. Thus, the use of the articles “a”, “an”, and “the” are not necessarily meant to refer to only a single component.

Moreover, unless otherwise indicated, percentages refer to percents by dry weight.

The imageable elements used in the practice of this invention are generally “single-layer” imageable elements by which we mean that the elements contain only one layer that is essential for imaging, but such elements further include one or more non-imageable layers under or over the imageable layer for various purposes. As described in more detail below, these imageable elements include a protective topcoat disposed over the imageable layer.

When “(meth)” is used as part of a monomer name, such as “(meth)acrylate”, it means the term includes both the methylated and non-methylated monomers, such as both acrylate and methacrylate.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

“Graft” polymer or copolymer refers to a polymer having a side chain that has a molecular weight of from about 200.

The term “polymer” refers to high and low molecular weight polymers including oligomers and includes homopolymers and copolymers.

The term “copolymer” refers to polymers that are derived from two or more different monomers.

The term “backbone” refers to the chain of atoms in a polymer to which a plurality of pendant groups are attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Radiation-Sensitive Compositions

The imageable elements used in the method include a radiation-sensitive composition that is usually used to form an imageable layer and may have any utility wherever there is a need for a coating that is polymerizable using suitable electromagnetic radiation, and particularly where it is desired to remove non-exposed regions of the coated and imaged composition. The method can be used to prepare printed circuit boards for integrated circuits (printing circuit boards), color filters, chemically amplified resists, imprint lithography, microelectronic and microoptical devices, and photomask lithography, and preferably printed forms such as lithographic printing plate precursors and imaged printing plates that are defined in more detail below.

The free radically polymerizable component used in the imageable layer consists of one or more compounds that have one or more ethylenically unsaturated polymerizable or crosslinkable groups that can be polymerized or crosslinked using free radical initiation. For example, the free radically polymerizable component can be ethylenically unsaturated monomers, oligomers, and crosslinkable polymers, or various combinations of such compounds.

Thus, suitable ethylenically unsaturated compounds that can be polymerized or crosslinked include ethylenically unsaturated polymerizable monomers that have one or more of the polymerizable groups, including unsaturated esters of alcohols, such as (meth)acrylate esters of polyols. Oligomers and/or prepolymers, such as urethane (meth)acrylates, epoxide (meth)acrylates, polyester (meth)acrylates, polyether (meth)acrylates, free-radical crosslinkable polymers, and unsaturated polyester resins can also be used. In some embodiments, the radically polymerizable component may comprise carboxy groups.

Particularly useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers, or combinations of these classes of materials. More particularly useful free radically polymerizable compounds include those derived from urea urethane (meth)acrylates or urethane (meth)acrylates having multiple polymerizable groups. Other preferred free radically polymerizable compounds are available from Sartomer Company, Inc. such as SR399 (dipentaerythritol pentaacrylate), SR355 (di-trimethylolpropane tetraacrylate), SR295 (pentaerythritol tetraacrylate), and others that would be readily apparent to one skilled in the art.

Also useful are urea urethane (meth)acrylates and urethane (meth)acrylates described in U.S. Pat. No. 6,582,882 (noted above) and U.S. Pat. No. 6,899,994 (noted above), and in copending and commonly assigned U.S. Ser. No. 11/196,124 (filed Aug. 3, 2005 by Saraiya et al.) that is incorporated by reference.

Still other useful free radically polymerizable compounds include monomers with urea, oxazolidinone, imidazolidinone, pyrimidone, or carbamate groups in addition to ethylenically unsaturated groups.

Numerous other free radically polymerizable compounds are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (noted above), beginning with paragraph [0170].

The free radically polymerizable component is present in the imageable layer in an amount sufficient to render the composition insoluble during development after exposure to radiation. This is generally from about 20 to about 70 weight % and preferably from about 30 to about 50 weight % based on the dry weight. For example, the weight ratio of free radically polymerizable component to the polymeric binder (described below) is generally from about 5:95 to about 95:5, preferably from about 10:90 to about 90:10, and more preferably from about 30:70 to about 70:30.

The imageable layer also includes an initiator composition that is capable of generating radicals sufficient to initiate polymerization of the radically polymerizable component upon exposure to the imaging radiation. The initiator composition may be responsive, for example, to electromagnetic radiation in the ultraviolet, visible and/or infrared spectral regions, corresponding to the broad spectral range of from about 150 nm to about 1500 nm. UV and visible light sensitivity is generally from about 150 nm to about 700 nm. In some embodiments, the initiator composition is responsive to infrared or near infrared radiation in the range of from about 600 nm to about 1300 nm, and more preferably to infrared radiation in the range of from about 700 nm to about 1200 nm. In preferred embodiments, the initiator composition is responsive to radiation having a km, of from about 150 to about 450 nm, and preferably of from about 375 to about 450 nm.

There are numerous compounds known in the literature that can be used in this manner including but not limited to, organic boron salts, s-triazines, benzoyl-substituted compounds, onium salts (such as iodonium, sulfonium, diazonium, and phosphonium salts), trihaloalkyl-substituted compounds, metallocenes (such as titanocenes), ketoximes, thio compounds, organic peroxides, or a combination of two or more of these classes of compounds. The organic boron salts, s-triazines, iodonium salts, and hexaarylbisimidazoles, or combinations thereof, are preferred.

Other suitable initiator compositions comprise compounds that include but are not limited to, amines (such as alkanol amines), thiol compounds, anilinodiacetic acids or derivatives thereof, N-phenyl glycine and derivatives thereof, N,N-dialkylaminobenzoic acid esters, N-arylglycines and derivatives thereof (such as N-phenylglycine), aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, alkyltriarylborates, tetraarylborates, trihalogenomethylarylsulfones, benzoin ethers and esters, peroxides (such as benzoyl peroxide), hydroperoxides (such as cumyl hydroperoxide), azo compounds (such as azo bis-isobutyronitrile) as described for example in U.S. Pat. No. 4,565,769 (Dueber et al.), borate and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts). Other known initiator composition components are described for example in U.S. Patent Application Publication 2003/0064318 (Huang et al.).

Particularly useful initiator composition components for UV and visible light sensitive radiation-sensitive compositions include hexaarylbiimidazoles (also known as triarylimidazolyl dimers) such as, for example, 2,2′-bis(2-chlorophenyl)-4,4′,5,5′-tetraphenyl-biimidazole and 2,2′-bis(o-chlorophenyl-4,4′,5,5′-tetra(m-methoxyphenyl)biimidazole. The triazines noted below can be used with exposure to imaging radiation at about any wavelength including UV and visible radiation exposure.

Other UV radiation-sensitive free-radical generating compounds include but are not limited to, trichloromethyl triazines as described, for example, in U.S. Pat. No. 4,997,745 (Kawamura et al.) and diaryliodonium salts.

Co-initiators can also be used, such as metallocenes (such as titanocenes and ferrocenes), mono- and polycarboxylic acids such as anilino diacetic acid, haloalkyl triazines, thiols or mercaptans (such as mercaptotriazoles), borate salts, and photooxidants containing a heterocyclic nitrogen that is substituted by an alkoxy or acyloxy group, as described in U.S. Pat. No. 5,942,372 (West et al.).

For IR-sensitive radiation-sensitive compositions, the preferred initiator compositions comprise an onium salt including but not limited to, a sulfonium, oxysulfoxonium, oxysulfonium, sulfoxonium, ammonium, selenonium, arsonium, phosphonium, diazonium, or halonium salt. Further details of useful onium salts, including representative examples, are provided in U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, suitable phosphonium salts include positive-charged hypervalent phosphorus atoms with four organic substituents. Suitable sulfonium salts such as triphenylsulfonium salts include a positively-charged hypervalent sulfur with three organic substituents. Suitable diazonium salts possess a positive-charged azo group (that is —N═N⁺). Suitable ammonium salts include a positively-charged nitrogen atom such as substituted quaternary ammonium salts with four organic substituents, and quaternary nitrogen heterocyclic rings such as N-alkoxypyridinium salts. Suitable halonium salts include a positively-charged hypervalent halogen atom with two organic substituents. The onium salts generally include a suitable number of negatively-charged counterions such as halides, hexafluorophosphate, thiosulfate, hexafluoroantimonate, tetrafluoroborate, sulfonates, hydroxide, perchlorate, n-butyltriphenyl borate, tetraphenyl borate, and others readily apparent to one skilled in the art. The halonium salts are more preferred, and the iodonium salts are most preferred.

Particularly useful boron components include organic boron salts that include an organic boron anion such as those described in the noted U.S. Pat. No. 6,569,603 that is paired with a suitable cation such as an alkali metal ion, an onium, or a cationic sensitizing dye. Useful onium cations include but are not limited to, ammonium, sulfonium, phosphonium, iodonium, and diazonium cations.

Some useful initiator compositions include one or more azine compounds as described for example in U.S. Pat. No. 6,936,384 (Munnelly et al.). These compounds are organic heterocyclic compounds containing a 6-membered ring formed from carbon and nitrogen atoms. Azine compounds include heterocyclic groups such as pyridine, diazine, and triazine groups, as well as polycyclic compounds having a pyridine, diazine, or triazine substituent fused to one or more aromatic rings such as carbocyclic aromatic rings. Thus, the azine compounds include, for example, compounds having a quinoline, isoquinoline, benzodiazine, or naphthodiazine substituent. Both monocyclic and polycyclic azine compounds are useful.

Especially useful azine compounds are triazine compounds that include a 6-membered ring containing 3 carbon atoms and 3 nitrogen atoms such as those described in U.S. Pat. No. 6,309,792 (Hauck et al.), U.S. Pat. No. 6.010,824 (Komano et al.), U.S. Pat. No. 5,885,746 (Iwai et al), U.S. Pat. No. 5,496,903 (Watanabe et al.), and U.S. Pat. No. 5,219,709 (Nagasaka et al.).

The azinium form of azine compounds can also be used if desired. In azinium compounds, a quaternizing substituent of a nitrogen atom in the azine ring is capable of being released as a free radical. The alkoxy substituent that quaternizes a ring nitrogen atom of the azinium nucleus can be selected from among a variety of alkoxy substituents.

Halomethyl-substituted triazines, such as trihalomethyl triazines, may be useful in the initiator composition. Representative compounds of this type include but are not limited to, 1,3,5-triazine derivatives such as those having 1 to 3 -CX₃ groups wherein X independently represent chlorine or bromine atoms, including polyhalomethyl-substituted triazines and other triazines, such as 2,4-trichloromethyl-6-methoxyphenyl triazine, 2-phenyl-4,6-bis(trichloromethyl)-s-triazine, 2,4,6-tris(trichloromethyl)-s-triazine, 2-methyl-4,6-bis(trichloromethyl)-s-triazine, 2-(styryl-4,6-bis(trichloromethyl)-s-triazine, 2-(p-methoxystyryl)-4,6-bis(trichloromethyl)-s-triazine, 2-(4-methoxy-naphtho-1-yl)-4,6-bis(trichloromethyl)-s-triazine, 2-(4-ethoxynaphtho-1yl)-4,6-bis(trichloromethyl)-s-triazine, and 2-(4-(2-ethoxyethyl)-naphtho-1-yl)-4,6-bis(trichloromethyl)-s-triazine], 2-(4-methylthiophenyl)-4,6-bis(trichloromethyl)-2-triazine, 2-(4-chlorophenyl-4,6-bis(trichloromethyl)-2-triazine, 2,4,6-tri(trichloromethyl)-2-triazine, and 2,4,6-tri(tribromomethyl)-2-triazine.

The azine compounds and particularly the triazine compounds may be used alone or in combination with one or more co-initiators such as titanocenes, mono- and polycarboxylic acids, and hexaarylbisimidazoles, as described for example in U.S. Pat. No. 4,997,745 (Kawamura et al.).

In some embodiments, the imageable layer also includes a mercaptan derivative such as a mercaptotriazole such as 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-(p-aminophenyl)-3-mercapto-1,2,4-triazole. Various mercaptobenzimidazoles, mercaptobenzothiazoles, and mercaptobenzoxazoles may also be present.

Thus, several initiator/co-initiator combinations can be used in various embodiments, namely:

a) a hexaarylbiimidazole as described above in combination with a co-initiator that is a mercaptotriazole as described above.

b) an iodonium salt (such as an iodonium borate) as described above in combination with a co-initiator that is a mercaptotriazole as described above.

c) a triazine as described above in combination with a co-initiator that is an N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof) as described above,

d) a triazine as described above in combination with a co-initiator that is a mercaptan derivative as described above, and

e) an iodonium salt (such as an iodonium borate) as described above in combination with a co-initiator that is a metallocene (for example a titanocene or ferrocene) as described for example in U.S. Pat. No. 6,936,384 (noted above).

The initiator composition including one or more initiator compounds is generally present in the imageable layer in an amount of from about 0.5% to about 30%, based on the dry weight of the coated imageable layer. Preferably, the initiator composition is present in an amount of from about 2% to about 20 weight %.

The imageable layer includes one or more polymeric binders. These polymeric binders generally have a molecular weight of from about 2,000 to about 1,000,000 and preferably from about 10,000 to about 200,000. The acid value (mg KOH/g) of the polymeric binder is generally from about 0 to about 400 as determined using known methods. Such polymeric binders can be particulate or film-forming in nature. Preferably, the polymeric binders are at least partially present as discrete particles.

Useful polymeric binders are dispersible, developable, or soluble in water or water/solvent mixtures such as fountain solutions, or combinations of fountain solutions and lithographic printing inks. Such polymeric binders include polymeric emulsions, dispersions, or graft polymers having pendant poly(alkyleneoxide) side chains that can render the imageable elements as “on-press” developable. Such polymeric binders are described for example in U.S. Pat. No. 6,582,882 (noted above) and U.S. Pat. No. 6,899,994 (Huang et al.). In some instances, these polymeric binders are present in the imageable layer at least partially as discrete particles.

Other useful polymeric binders have hydrophobic backbones and comprise both of the following a) and b) recurring units, or the b) recurring units alone:

a) recurring units having pendant cyano groups attached directly to the hydrophobic backbone, and

b) recurring units having pendant groups comprising poly(alkylene oxide) segments.

These polymeric binders comprise poly(alkylene oxide) segments and preferably poly(ethylene oxide) segments. These polymers can be graft copolymers having a main chain polymer and poly(alkylene oxide) pendant side chains or segments or block copolymers having blocks of (alkylene oxide)-containing recurring units and non(alkylene oxide)-containing recurring units. Both graft and block copolymers can additionally have pendant cyano groups attached directly to the hydrophobic backbone. The alkylene oxide constitutional units are generally C₁ to C₆ alkylene oxide groups, and more typically C₁ to C₃ alkylene oxide groups. The alkylene portions can be linear or branched or substituted versions thereof. Poly(ethylene oxide) and poly(propylene oxide) segments are preferred and poly(ethylene oxide) segments are most preferred.

In some embodiments, the polymeric binders contain only recurring units comprising poly(alkylene oxide) segments, but in other embodiments, the polymeric binders comprise recurring units comprising the poly(alkylene oxide) segments as well as recurring units having pendant cyano groups attached directly to the hydrophobic backbone. By way of example only, such recurring units can comprise pendant groups comprising cyano, cyano-substituted alkylene groups, or cyano-terminated alkylene groups. Recurring units can also be derived from ethylenically unsaturated polymerizable monomers such as acrylonitrile, methacrylonitrile, methyl cyanoacrylate, ethyl cyanoacrylate, or a combination thereof. However, cyano groups can be introduced into the polymer by other conventional means. Examples of such cyano-containing polymeric binders are described for example in U.S. Patent Application Publication 2005/003285 (Hayashi et al.). Preferably, such polymers include poly(alkylene glycol) groups as first pendant groups and cyano groups as second pendant groups, and the molar ratio of second pendant groups to first pendant groups is from about 14:1 to about 1000:1 and preferably from about 30:1 to about 200:1.

By way of example, such polymeric binders can be formed by polymerization of a combination or mixture of suitable ethylenically unsaturated polymerizable monomers or macromers, such as:

A) acrylonitrile, methacrylonitrile, or a combination thereof,

B) poly(alkylene oxide) esters of acrylic acid or methacrylic acid, such as poly(ethylene glycol) methyl ether acrylate, poly(ethylene glycol) methyl ether methacrylate, or a combination thereof, and

C) optionally, monomers such as acrylic acid, methacrylic acid, styrene, hydroxystyrene, acrylate esters, methacrylate esters, acrylamide, methacrylamide, or a combination of such monomers.

Particularly useful combinations of monomers include one or more (meth)acrylonitriles, one or more poly(alkylene glycol) methyl ether (meth)acrylates, and one or more of styrene and styrene derivatives.

The amount of the poly(alkylene oxide) segments in such polymeric binders is from about 0.5 to about 60 weight %, preferably from about 2 to about 50 weight %, more preferably from about 5 to about 40 weight %, and most preferably from about 5 to about 20 weight %. The amount of (alkylene oxide) segments in the block copolymers is generally from about 5 to about 60 weight %, preferably from about 10 to about 50 weight %, and more preferably from about 10 to about 30 weight %.

The polymeric binders can be present in an amount of from about 10 to about 50%, and preferably from about 20 to about 50%, based on the dry weight of the imageable layer.

Examples of polymeric binders include but are not limited to, those derived at least in part from one or more monomers having pendant carboxyl groups such as (meth)acrylic acids, (meth)acrylates, (meth)acrylamides, (meth)acrylonitriles, poly(alkylene glycols), poly(alkylene glycol) (meth)acrylates, vinyl acetals, styrene and substituted styrenes, N-substituted cyclic imides or maleic anhydrides, such as those described in EP 1,182,033 (noted above) and U.S. Pat. No. 6,309,792 (noted above), U.S. Pat. No. 6,352,812 (Shimazu et al.), U.S. Pat. No. 6,569,603 (noted above), and U.S. Pat. No. 6,893,797 (noted above). Phenolic resins are also useful. Also useful are the vinyl carbazole polymers having pendant N-carbazole moieties including those described in U.S. Pat. No. 4,774,163 (Higashi) and polymers having pendant vinyl groups including those described in U.S. Pat. No. 4,511,645 (Koike et al.) and EP 1,182,033A1 (Fujimaki et al.).

Still other useful polymeric binders are represented by the following Structure (I):

-(A)ₓ-(B)_{y}—(C)_{z}— (I)

wherein A represents recurring units comprising a pendant —C(═O)O—CH₂CH═CH₂ group, B represents recurring units comprising pendant cyano groups, and C represents recurring units other than those represented by A and B.

Preferably, B represents recurring units derived from (meth)acrylonitrile, and C represents recurring units derived from one or more (meth)acrylic acid esters, (meth)acrylamides, vinyl carbazole, styrene and styrenic derivatives thereof, N-substituted maleimides, (meth)acrylic acid, maleic anhydride, vinyl acetate, vinyl ketones (such as vinyl methyl ketone), vinyl pyridines, N-vinyl pyrrolidones, 1-vinylimidazole, and vinyl polyalkylsilanes (such as vinyl trimethylsilane). Most preferably, B represents recurring units derived from acrylonitrile, and C is derived from one or more of methacrylic acid, acrylic acid, vinyl carbazole, methyl methacrylate, 2-hydroxyethyl methacrylate, styrene, and N-phenylmaleimide.

The polymeric binders of Structure (I) generally have a molecular weight of from about 2,000 to about 1,000,000 and preferably from about 10,000 to about 200,000. The acid value (mg KOH/g) of the polymeric binder is generally from about 20 to about 400 as determined using known methods.

The radiation-sensitive composition may include particles of a poly(urethane-acrylic) hybrid that are distributed (usually uniformly) throughout the composition. This hybrid has a molecular weight of from about 50,000 to about 500,000 and the particles have an average particle size of from about 10 to about 10,000 nm (preferably from about 30 to about 500 nm and more preferably from about 30 to about 150 nm). These hybrids can be either “aromatic” or “aliphatic” in nature depending upon the specific reactants used in their manufacture. Blends of particles of two or more poly(urethane-acrylic) hybrids can also be used. Details about manufacturing methods and properties of the poly(urethane-acrylic) hybrids are provided by Galgoci et al. in JCT Coatings Tech. 2(13), 28-36 (February 2005).

Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that may also include commercial surfactants, anti-foaming agents, dispersing agents, anti-corrosive agents, and optionally pigments and water-miscible organic solvents. Further details about each commercial Hybridur® polymer dispersion can be obtained by visiting the Air Products and Chemicals, Inc. website.

The imageable layer also includes a radiation absorbing compound (sometimes called a “sensitizer”) that is sensitive to radiation at a desired wavelength. These compounds absorb the radiation and facilitate polymerization during imaging. The radiation absorbing compounds can be sensitive to radiation having a wavelength of from about 150 to about 1400 nm. The compounds sensitive to UV and visible radiation generally have a λₘₐₓ of from about 150 to about 600 nm.

In some preferred embodiments, the imageable layer contains a UV sensitizer where the free-radical generating compound is UV radiation sensitive (that is at least 150 nm and up to and including 450 nm), thereby facilitating photopolymerization. Typical UV radiation-sensitive free-radical generating compounds are described above. In some most preferred embodiments, the imageable layer is sensitized to “violet” radiation in the range of at least 375 nm and up to and including 450 nm. Useful sensitizers for such compositions include certain pyrilium and thiopyrilium dyes and 3-ketocoumarins (particularly in combination with a polycarboxylic acid free radical generating compound, such as anilino-N,N-diacetic acid).

Sensitizers that absorb in the visible region of the electromagnetic spectrum (that is at least 400 nm and up to and including 650 nm) can also be used. Examples of such sensitizers are well known in the art and include the compounds described in Cols. 17-22 of U.S. Pat. No. 6,569,603 (noted above) that is incorporated herein by reference. Other useful visible and UV-sensitive sensitizing compositions include a cyanine dye, diaryliodonium salt, and a co-initiator (as described above) as described in U.S. Pat. No. 5,368,990 (Kawabata et al.).

Other useful sensitizers for the violet/visible region of sensitization are the 2,4,5-triaryloxazole derivatives as described in WO 2004/074930 (Baumann et al.). These compounds can be used alone or with a co-initiator as described above, and especially with the 1,3,5-triazines described above or with thiol compounds. Useful 2,4,5-triaryloxazole derivatives can be represented by the Structure G-(Ar₁)₃ wherein Ar₁ is the same or different, substituted or unsubstituted carbocyclic aryl group having 6 to 12 carbon atoms in the ring, and G is a furan, oxazole, or oxadiazole ring. The Ar₁ groups can be substituted with one or more halo, substituted or unsubstituted alkyl, substituted or unsubstituted cycloalkyl, substituted or unsubstituted aryl, amino (primary, secondary, or tertiary), or substituted or unsubstituted alkoxy or aryloxy groups. Thus, the aryl groups can be substituted with one or more R′₁ through R′₃ groups, respectively, that are independently hydrogen or a substituted or unsubstituted alkyl group having from 1 to 20 carbon atoms (such as methyl, ethyl, isopropyl, n-hexyl, benzyl, and methoxymethyl groups) substituted or unsubstituted carbocyclic aryl group having 6 to 10 carbon atoms in the ring (such as phenyl, naphthyl, 4-methoxyphenyl, and 3-methylphenyl groups), substituted or unsubstituted cycloalkyl group having 5 to 10 carbon atoms in the ring, a —N(R′₄)(R′₅) group, or a —OR′₆ group wherein R′₄ through R′₆ independently represent substituted or unsubstituted alkyl or aryl groups as defined above. Preferably, at least one of R′₁ through R′₃ is an —N(R′₄)(R′₅) group wherein R′₄ and R′₅ are the same or different alkyl groups. Preferred substituents for each Ar₁ group include the same or different primary, secondary, and tertiary amines and more preferably they are the same dialkylamines.

Still another class of useful violet/visible radiation sensitizers includes compounds represented by the Structure Ar₁-G-Ar₂ wherein Ar₁ and Ar₂ are the same or different substituted or unsubstituted aryl groups having 6 to 12 carbon atoms in the ring, or Ar₂ can be an arylene-G-Ar₁ or arylene-G-Ar₂ group, and G is a furan, ozazole, or oxadiazole ring. Ar₁ is the same as defined above, and Ar₂ can be the same or different aryl group as Ar₁. “Arylene” can be any of the aryl groups defined for Ar₁ but with a hydrogen atom removed to render them divalent in nature.

Additional useful “violet”-visible radiation sensitizers are the compounds described in WO 2004/074929 (Baumann et al.) that is also incorporated herein by reference. These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

The imageable layer can alternatively be sensitive to infrared and near-infrared radiation, that is, a wavelength of from about 600 to about 1400 nm and preferably of from about 700 to about 1200 nm. Such radiation absorbing compounds include carbon blacks and other IR-absorbing pigments and various IR-sensitive dyes (“IR dyes”), which are preferred.

Examples of suitable IR dyes include but are not limited to, azo dyes, squarilium dyes, croconate dyes, triarylamine dyes, thiazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,569,603 (noted above), and U.S. Pat. No. 6,787,281 (noted above), and EP Publication 1,182,033A1 (noted above). In addition to low molecular weight IR-absorbing dyes, IR dye moieties bonded to polymers can be used as well.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), and U.S. Pat. No. 5,496,903 (Watanate et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (DeBoer).

The radiation absorbing compound can be present in the imageable layer in an amount generally of from about 4% to about 20% and preferably from about 4 to about 15%, based on the total dry layer weight. Alternatively, the amount can be defined by an absorbance in the range of from about 0.05 to about 3, and preferably of from about 0.1 to about 1.5, in the dry film as measured by reflectance UV-visible spectrophotometry. The particular amount needed for this purpose would be readily apparent to one skilled in the art, depending upon the specific compound used.

The imageable layer can also include a poly(alkylene glycol) or an ether or ester thereof that has a molecular weight of from about 200 to about 4000 (preferably from about 500 to about 2000). This additive can be present in an amount of from about 2 to about 50 weight % (preferably from about 5 to about 30%) based on the total dry layer weight. Particularly useful additives of this type include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate. Also useful are SR9036 (ethoxylated (30) bisphenol A dimethacrylate), CD9038 (ethoxylated (30) bisphenol A diacrylate), and SR494 (ethoxylated (5) pentaerythritol tetraacrylate), and similar compounds all of which that can be obtained from Sartomer Company, Inc.

The imageable layer can also include a variety of optional compounds including but not limited to, dispersing agents, humectants, biocides, plasticizers, surfactants for coatability or other properties, viscosity builders, dyes or colorants to allow visualization of the written image, pH adjusters, drying agents, defoamers, preservatives, antioxidants, development aids, organic or inorganic salts, rheology modifiers or combinations thereof, or any other addenda commonly used in the lithographic art, in conventional amounts.

### Imageable Elements

Imageable elements are formed by suitable application of a radiation-sensitive composition containing the components described above to a suitable substrate to form an imageable layer. This substrate can be treated or coated in various ways as described below prior to application of the radiation-sensitive composition. Preferably, there is only a single imageable layer comprising the radiation-sensitive composition of this invention. If the substrate has been treated to provide an “interlayer” for improved adhesion or hydrophilicity, the applied radiation-sensitive composition is generally considered the “top” or outermost layer. These interlayers, however, are not considered “imageable layers”.

The imageable elements have what is conventionally known as an protective overcoat or topcoat (such as an oxygen impermeable or oxygen barrier) disposed on the imageable layer(s) as described in WO 99/06890 (Pappas et al.). Such overcoat layers or protective topcoats comprise one or more water-soluble polymers such as poly(vinyl alcohol), poly(vinyl pyrrolidone), poly(vinyl pyrrolidone/vinyl acetate), poly(ethyl oxazoline), and poly(vinyl imidazole), or mixtures thereof, and the topcoat generally has a dry coating weight of from about 0.1 to about 4 g/m². Surfactants may also be present. Preferably, the protective topcoat includes a mixture of poly(vinyl alcohol) and poly(vinyl pyrrolidone) in an amount of total polymers of from about 85 to 100 weight % based on the total dry topcoat weight. The poly(vinyl alcohol) is the predominant polymer.

The substrate generally has a hydrophilic surface, or from about a surface that is more hydrophilic than the applied radiation-sensitive composition on the imaging side. The substrate comprises a support that can be composed of any material that is conventionally used to prepare imageable elements such as lithographic printing plates. It is usually in the form of a sheet, film, or foil, and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports may be modified on one or both flat surfaces with a “subbing” layer to enhance hydrophilicity, or paper supports may be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

A preferred substrate is composed of an aluminum support that may be treated using techniques known in the art, including physical graining, electrochemical graining, chemical graining, and anodizing. Preferably, the aluminum sheet is electrochemically anodized using phosphoric acid or sulfuric acid and conventional procedures.

An interlayer may be formed by treatment of the aluminum support with, for example, a silicate, dextrine, calcium zirconium fluoride, hexafluorosilicic acid, a phosphate solution containing a fluoride such as sodium fluoride (PF), poly(vinyl phosphoric acid) (PVPA), vinyl phosphonic acid copolymer, poly(acrylic acid), or acrylic acid copolymer. Preferably, the aluminum support is grained, phosphoric acid-anodized, and treated with poly(acrylic acid) using known procedures to improve surface hydrophilicity.

The thickness of the substrate can be varied but should be sufficient to sustain the wear from printing and thin enough to wrap around a printing form. Preferred embodiments include a treated aluminum foil having a thickness of from about 100 to about 600 μm.

The backside (non-imaging side) of the substrate may be coated with antistatic agents and/or slipping layers or a matte layer to improve handling and “feel” of the imageable element.

The substrate can also be a cylindrical surface having the radiation-sensitive composition applied thereon, and thus be an integral part of the printing press. The use of such imaging cylinders is described for example in U.S. Pat. No. 5,713,287 (Gelbart).

The radiation-sensitive composition containing the desired components can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder).

Illustrative of such manufacturing methods is mixing the radically polymerizable component, initiator composition, radiation absorbing compound, polymeric binder(s), and any other components of the radiation-sensitive composition in a suitable organic solvent [such as methyl ethyl ketone (2-butanone), methanol, ethanol, 1-methoxy-2-propanol, isopropyl alcohol, acetone, y-butyrolactone, n-propanol, tetrahydrofuran, and others readily known in the art, as well as mixtures thereof], applying the resulting solution to a substrate, and removing the solvent(s) by evaporation under suitable drying conditions. Preferred coating solvents and representative imageable layer formulations are described in the Examples below. After proper drying, the coating weight of the imageable layer is generally from about 0.1 to about 5 g/m², preferably from about 0.5 to about 3.5 g/m², and more preferably from about 0.5 to about 2 g/m².

The imageable elements have any useful form including but not limited to, printing plate precursors, printing cylinders, printing sleeves and printing tapes (including flexible printing webs). Preferably, the imageable members are printing plate precursors that can be of any useful size and shape (for example, square or rectangular) having the requisite imageable layer disposed on a suitable substrate. Printing cylinders and sleeves are known as rotary printing members having the substrate and imageable layer in a cylindrical form. Hollow or solid metal cores can be used as substrates for printing sleeves.

### Imaging Conditions

During use, the imageable element is exposed to a suitable source of radiation such as UV, visible light, near-infrared, or infrared radiation, depending upon the radiation absorbing compound present in the radiation-sensitive composition, at a wavelength of from about 150 nm to about 1500 nm. In some embodiments, imaging is carried out using an infrared laser at a wavelength of from about 700 nm to about 1200 nm. The laser used to expose the imageable element is preferably a diode laser, because of the reliability and low maintenance of diode laser systems, but other lasers such as gas or solid-state lasers may also be used. The combination of power, intensity and exposure time for laser imaging would be readily apparent to one skilled in the art.

The imaging apparatus can be configured as a flatbed recorder or as a drum recorder, with the imageable member mounted to the interior or exterior cylindrical surface of the drum. An example of an useful imaging apparatus is available as models of Luxel V and Vx imagesetters available from Fujifilm (Japan) that contains laser diodes that emit radiation at a wavelength of about 405 nm. Other suitable imaging sources include the :Advantage and :Avalon imagesetters (available from Agfa-Gevaert, Belgium) and the MAKO NEWS platesetter (available from ECRM, Tewksbury, Mass.).

Imagesetters that contain laser diodes that emit near infrared radiation at a wavelength of about 830 nm include the Creo Trendsetter® imagesetters available from Eastman Kodak Company. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.).

Imaging radiation in the UV to visible region of the spectrum, and particularly the UV region (for example at least 250 nm and up to and including 450 nm), can be carried out generally using energies of at least 0.01 mJ/cm² and up to and including 0.5 mJ/cm², and preferably at least 0.02 and up to and including about 0.1 mJ/cm². It would be desirable, for example, to image the UV/visible radiation-sensitive imageable elements at a power density in the range of at least 0.5 and up to and including 50 kW/cm² and preferably of at least 5 and up to and including 30 kW/cm².

Infrared imaging can be carried out generally at an imaging energy of from about 20 mJ/cm² to about 500 mJ/cm², preferably from about 50 and up to 300 mJ/cm².

### Development and Printing

After imaging, the imaged element can be subjected to a post exposure bake step using known conditions (such as the conditions in the Examples). Preferably, this step is omitted.

After exposure and any post exposure bake step, the imagewise exposed element is rinsed with water or another aqueous solution to remove, at least partially (at least 50 weight %) and preferably substantially all (at least 90 weight %) of the water-soluble topcoat. This pre-rinse step can be carried out in a rinsing chamber of a conventional processor (see Examples below), by using a single stage dip tank or spray processor filled with an aqueous solution, or by rubbing or wiping the outer layer of the imaged element with an applicator containing the aqueous solution. Alternatively, the imaged element can be brushed with the aqueous solution or the solution may be applied by spraying the outer layer with sufficient force to remove the topcoat. Still again, the imaged element can be immersed in the aqueous solution. Rinsing is preferably carried out using water, but an aqueous solution that incompletely or not at all removes the non-exposed regions of the imageable layer can also be used. Such aqueous solutions include but are not limited to, alkaline solutions, acidic solutions, or solutions containing a compound used to protect the plate such as gum arabic. The aqueous solution may also contain surfactants, buffering agents, or biocides.

The pre-rinse step can be carried out under various time and temperature conditions to achieve the desired result. Generally, it is carried out for from about 2 to about 30 seconds at from about 15 to about 80° C. (preferably from about 20 to about 40° C.).

After the pre-rinse step, the imagewise exposed elements are mounted on a printing press and developed “on-press”. This type of development avoids the use of the conventional alkaline developing solutions. The mounted imaged element is then contacted with a fountain solution, lithographic printing ink, or both, in any order, to remove the non-exposed (non-imaged) regions in the imaged layer (that is, development) as printing is begun. Preferably, the element is contacted first with a fountain solution and then with the lithographic printing ink, and printing is begun simultaneously with the inking.

Typical ingredients of aqueous fountain solutions include pH buffers, desensitizing agents, surfactants and wetting agents, humectants, low boiling solvents, biocides, antifoaming agents, and sequestering agents. A representative example of a fountain solution is Varn Litho Etch 142W+Varn PAR (alcohol sub) (available from Varn International, Addison, Ill.).

When printing is begun, the fountain solution is taken up by the non-exposed regions, and ink is taken up by the imaged (exposed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means.

The following examples are provided to illustrate the practice of the invention but are by no means intended to limit the invention in any manner.

### EXAMPLES

The components and materials used in the examples and analytical methods used in evaluation were as follows:

Acticryl CL 959 is 2-propenoic acid, 2-(2-oxo-3-oxazolidinyl)ethyl ester that was obtained from SNPE (Bergerac, France).

Acticryl CL 960 is 2-propenoic acid, 2-[[(1-methylethoxy)carbonyl]amino]ethyl ester that was also obtained from SNPE.

Airvol® 203 is a polyvinyl alcohol (Mw 13,000-23,000 and 87-89% hydrolyzed) that was available from Air Products and Chemicals, Inc. (Allentown, Pa.).

BLO represents γ-butyrolactone.

Byk® 307 is a polyethoxylated dimethyl polysiloxane copolymer that was obtained from Byk Chemie (Wallingford, Conn.) in a 25 wt. % xylene/methoxypropyl acetate solution.

Copolymer 1 was prepared as described in US 20050003285 (Example 1) and was used as a 24% solids solution in 80:20 1-propanol:water.

Elvanol® 5105 is a poly(vinyl alcohol) that was obtained from Dupont (Wilmington, Del.).

FluorN2900 is a fluorourethane glycol surfactant that was obtained from Cytonix (Beltsville, Md.).

Hybridur® 580 is a urethane-acrylic hybrid polymer dispersion (40%) that was obtained from Air Products and Chemicals, Inc. (Allentown, Pa.).

IB05 represents bis(4-t-butylphenyl) iodonium tetraphenylborate.

IPA represents isopropyl alcohol.

IRT is an IR Dye that was obtained from Showa Denko (Japan).

Klucel E is a hydroxypropyl cellulose that was obtained from Hercules Inc., Aqualon Division (Wilmington, Del.) and was used as a 5% solution by weight in water.

Masurf® FS-1520 is a fluoroaliphatic betaine fluorosurfactant that was obtained from Mason Chemical Company (Arlington Heights, Ill.).

MEK represents methyl ethyl ketone.

N-BAMAAm represents benzoic acid methacrylamide or carboxyphenyl methacrylamide.

NK Ester A-DPH is a dipentaerythritol hexaacrylate that was obtained from Kowa American (New York, N.Y.).

o-Cl HABI represents 2,2′-Bis(o-chlorophenyl)-4,5,4′,5′-tetraphenylbiimidazole.

Oligomer A is an urethane acrylate prepared by reacting 2 parts of hexamethylene diisocyanate with 2 parts of hydroxyethyl methacrylate and 1 part of 2-(2-hydroxyethyl)piperidine.

Oligomer B is an 80 weight % solution in MEK of a urethane acrylate obtained by reaction of DESMODUR® N 100 with hydroxyethyl acrylate and pentaerythritol triacrylate.

PGME represents 1-methoxy-2-propanol and it is also known as Dowanol PM.

Phosmer PE is an ethylene glycol methacrylate phosphate with 4-5 ethoxy groups that was obtained from Uni-Chemical Co. Ltd. (Japan).

Pigment A (951) is a 27% solids dispersion of 7.7 parts of a polyvinyl acetal derived from poly(vinyl alcohol) acetalized with acetaldehyde, butyraldehyde, and 4-formylbenzoic acid, 76.9 parts of Irgalith Blue GLVO (Cu-phthalocyanine C.I. Pigment Blue 15:4) and 15.4 parts of Disperbyk® 167 dispersant (Byk Chemie) in 1-methoxy-2-propanol.

Pluronic L43 is a ethylene oxide/propylene oxide block copolymer surfactant that was obtained from BASF (Appleton, Wis.).

PVP K-15 represents a poly(vinyl pyrrolidone) that was obtained from International Specialty Products (Wayne, N.J.).

SR-349 is an ethoxylated Bisphenol A diacrylate available from Sartomer Company, Inc. (Exton, Pa.).

SR-399 is dipentaerythritol pentaacrylate that was obtained from Sartomer Company, Inc.

Substrate 1 represents an aluminum substrate that had been treated by brush-graining and anodizing with phosphoric acid, followed by coating it with 0.02 g/m² poly(acrylic acid) to form a hydrophilic surface.

Substrate 2 represents an aluminum substrate that had been treated by electrochemically graining and anodizing with sulfuric acid, followed by a post-treatment with poly(vinyl phosphoric acid) to form a hydrophilic surface.

UV Dye has the following structure:

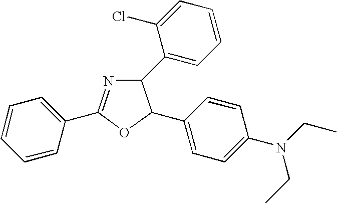

Vazo-64 is 2,2′-azobis(isobutyronitrile) (AIBN) that was obtained from Dupont de Nemours Co. (Wilmington, Del.).

### Synthesis of Copolymer 2:

Dimethylacetamide (65 g), N-BAMAAm (6.5 g), acrylonitrile (8.4 g), methacrylamide (1.7 g), N-phenyl maleimide (0.9 g), and Vazo-64 (0.175 g) were added to a 500 ml 4-neck ground glass flask, equipped with a heating mantle, temperature controller, mechanical stirrer, condenser, pressure equalized addition funnel and nitrogen inlet. The reaction mixture was heated to 80° C. under a nitrogen atmosphere. Then a pre-mixture of dimethylacetamide (100 g), N-BAMAAm (19.4 g), acrylonitrile (25.2 g), methacrylamide (5.3 g), N-phenyl maleimide (2.6 g), and Vazo-64 (0.35 g) were added over two hours at 80° C. The reaction was continued another eight hours and Vazo 64 (0.35 g) was added two more times. The polymer conversion was >99% based on a determination of percent of non-volatiles. The weight ratio of the resulting N-BAMAAm/-AN/methacrylamide/N-phenyl maleimide polymer was 37:48:10:5. The viscosity (G.H′33) was G+(˜170 cps) at 30% non-volatiles in dimethylacetamide.

The resin solution was precipitated in powder form using ethanol/water (60:40) and Lab Dispersator (4000 RPM) and filtered, and the slurry was re-dissolved in ethanol and filtered. The resulting powder was dried at room temperature for 48 hours. The resulting yield was 85% and the polymer acid number was 94.4 (actual) versus 95 (theoretical).

### Examples 1-12

Imageable layer coating compositions (Coatings 1-7) were prepared using the components described in TABLE I below. A topcoat coating formulation was prepared as described in TABLE II below.

TABLE I
(weight %)

| Component | Coating 1 | Coating 2 | Coating 3 | Coating 4 | Coating 5 | Coating 6 | Coating 7 |
|---|---|---|---|---|---|---|---|
| Copolymer 1 | 8.58 | 8.58 | 8.58 | 9.30 | 8.57 | 3.70 | 8.53 |
| (24% in 80:20 | | | | | | | |
| 1-propanol:water) | | | | | | | |
| SR-349 | 1.34 | 0 | 0 | 1.30 | 0 | 0.80 | 1.34 |
| SR-399 | 0 | 1.65 | 3.35 | 0 | 1.67 | 0 | 0 |
| (80% in MEK) | | | | | | | |
| Oligomer A | 4.47 | 4.47 | 0 | 4.35 | 0 | 2.70 | 4.47 |
| (30% in ethyl | | | | | | | |
| acetate) | | | | | | | |
| Oligomer B | 0 | 0 | 0 | 0 | 1.67 | 0 | 0 |
| (80% in MEK) | | | | | | | |
| Phosmer PE (10% | 0.67 | 0.67 | 0.67 | 0 | 0.67 | 0.35 | 0.67 |
| in PGME) | | | | | | | |
| Klucel E (5% in | 0 | 0 | 0 | 7.30 | 0 | 0 | 0 |
| water) | | | | | | | |
| UV Dye | 0.93 | 0.93 | 0.93 | 1.00 | 0.94 | 0.45 | 0.88 |
| o-Cl HABI | 0.23 | 0.23 | 0.23 | 0.25 | 0.24 | 0.10 | 0.19 |
| 1H-1,2,4-triazole- | 0.41 | 0.41 | 0.41 | 0.45 | 0.40 | 0.20 | 0.41 |
| 3-thiol | | | | | | | |
| Pigment A (27% in | 0.93 | 0.93 | 0.93 | 1.00 | 0.94 | 0.45 | 0.93 |
| PGME) | | | | | | | |
| Byk ® 307 (10% in | 0.13 | 0.13 | 0.13 | 0.15 | 0.14 | 0.05 | 0.13 |
| PGME) | | | | | | | |
| PGME | 57.43 | 57.12 | 57.43 | 51.15 | 57.42 | 60.15 | 0 |
| MEK | 20.54 | 20.54 | 19.87 | 18.55 | 19.87 | 21.25 | 18.70 |
| Ethyl acetate | 4.34 | 4.34 | 7.47 | 4.35 | 7.47 | 5.85 | 0.15 |
| 1-Propanol | 0 | 0 | 0 | 0.28 | 0 | 3.16 | 46.20 |
| Water | 0 | 0 | 0 | 0.57 | 0 | 0.79 | 17.40 |

TABLE II
(weight %)

| | |
|---|---|
| Airvol ® 203 (10% in water) | 28.00 |
| PVP K-15 | 0.15 |
| 2-Propanol | 3.88 |
| Water | 67.97 |

For each of Examples 1-12, the imageable layer formulation was coated onto Substrate 1 using a K303 bar coater (R.K. Print-Coat Instruments Ltd., United Kingdom) with a #3 wire wound bar and dried at approximately 80° C. for 15-35 seconds. The topcoat formulation was then coated on top of each dried imageable layer also using a K303 bar coater with a #3 wire wound bar and dried at approximately 80° C. for 20-60 seconds to provide an oxygen barrier layer.

The resulting imageable elements (printing plate precursors) were imagewise exposed on a Luxel Vx-6000 CTP imagesetter (Fuji Photo, Japan) with an exposure series from 1.8 to 185 μJ/cm². After imaging, the imaged elements were optionally subjected to a post-exposure bake step (PEB) at 110° C. for 20 seconds, and then passed through the pre-rinse section of a Raptor 85 plate processor (Glunz & Jensen, Denmark) containing water where the oxygen-barrier topcoat was at least partially removed, and at least some of the non-exposed imaged layer was removed. The amount of non-exposed imaged layer that was removed was qualitatively evaluated as follows:
0=coating completely removed
1=slight coating residue or stain remaining
2=more than half of coating removed
3=approximately half of coating removed
4=less than half of coating removed
5=very little or none of the coating removed

The resulting printing plates were each mounted on an AB Dick 9870 Offset Duplicator press without further processing. The press was charged with Van Son Rubber Base Black 10850 ink (Van Son Royal Dutch Printing, Holland) and fountain solution containing Varn Litho Etch 142 W at 3 oz./gal. (23.4 ml/liter) and PAR alcohol replacement at 3 oz./gal. (23.4 ml/liter) (both available from Varn International of Addison, Ill.). After printing 200 copies, the press was stopped. The printed sheets were evaluated for the number of impressions required for the non-exposed regions of the printed sheets to be clean of ink, and for the lowest exposure energy needed to show a completely printed solid after the 200 copies had printed. The results are provided below in TABLE VI and show that removal of the non- exposed regions was completed on-press to form a clean, non-printing background while the exposed (imaged) regions printed images at reasonable exposures.

### Examples 13-18

For each of Examples 13-18, an additional component was added to an aliquot of Coating 1 formulation to make imageable layer formulations identified as Coatings 8-10 in TABLE III.

TABLE III

| Component | Coating 8 | Coating 9 | Coating 10 |
|---|---|---|---|
| Pluronic ® L43 surfactant | 0.028 g | 0 | 0 |
| Sodium tetraphenylborate | 0 | 0.006 g | 0 |
| Tetrabutylammonium | 0 | 0 | 0.006 g |
| bromide | | | |
| Coating 1 solution | 10 g | 10 g | 10 g |

The imageable layer formulations were coated onto Substrate 1 and dried, and coated with the topcoat formulation, as described in Examples 1-12. The resulting imageable elements were imagewise exposed, optionally post exposure baked, pre-rinsed, mounted on press, and evaluated as described for Examples 1-12. The topcoat was at least partially removed in the pre-rinse step. The results are given below in TABLE VI and show that additional components will alter the cleanout time and imaging speed while still producing a printing plate where removal of the non-exposed regions was completed on-press to form a clean, non-printing background while the exposed (imaged) regions printed images at reasonable exposures.

### Examples 19-26

For each of Examples 19-26, a stock solution was made up using the components shown below in TABLE IV. Additional components were then added to an aliquot of the stock solution according to TABLE V.

TABLE IV

| | |
|---|---|
| Copolymer 1 (24% in 80:20 1-propanol:water) | 8.58 g |
| Phosmer PE (10% in PGME) | 0.67 g |
| UV Dye | 0.93 g |
| o-Cl HABI | 0.23 g |
| 1H-1,2,4-triazole-3-thiol | 0.41 g |
| Pigment A (27% in PGME) | 0.93 g |
| Byk ® 307 (10% in PGME) | 0.13 g |
| PGME | 57.41 g |
| MEK | 20.54 g |
| Ethyl acetate | 4.34 g |

TABLE V

| | | | | Coating |
|---|---|---|---|---|
| Component | Coating 11 | Coating 12 | Coating 13 | 14 |
| SR-349 | 0 | 0 | 0.14 g | 0.14 g |
| Oligomer A | 0.45 g | 0.44 g | 0 | 0 |
| (30% in ethyl | | | | |
| acetate) | | | | |
| Acticryl CL 959 | 0.15 g | 0 | 0.20 g | 0 |
| Acticryl CL 960 | 0 | 0.12 g | 0 | 0.17 g |
| Ethyl acetate | 0 | 0 | 0.32 g | 0.31 g |
| Stock solution | 9.44 g | 9.41 g | 9.41 g | 9.41 g |

The imageable layer formulations shown in TABLE V were coated onto Substrate 1, dried, and overcoated with the topcoat formulation as described for Examples 1-12. The resulting imageable elements (printing plate precursors) were imaged, optionally post exposure baked, pre-rinsed, mounted on press, and evaluated as described for Examples 1-12. The topcoat was at least partially removed in the pre-rinse step in each example. The results are given below in TABLE VI. These results show that removal of the non-exposed regions was completed on press to form a clean, non-printing background while the exposed regions printed images at reasonable exposures.

TABLE VI

| | | Post- | | | Lowest exposure (μJ/cm²) |
|---|---|---|---|---|---|
| | | Exposure | Amount of imaging layer | Number of impressions | showing a completely printed |
| Example | Coating | Bake? | removed during the pre-rinse | for a clean background | solid after 200 copies |
| 1 | 1 | Yes | 2 | <25 | 15 |
| 2 | 2 | Yes | 3 | <25 | 15 |
| 3 | 3 | Yes | 3 | <25 | 21 |
| 4 | 4 | Yes | 2 | <25 | 10 |
| 5 | 5 | Yes | 4 | <25 | 31 |
| 6 | 6 | Yes | 1 | <25 | 15 |
| 7 | 7 | Yes | 2 | <25 | 10 |
| 8 | 1 | No | 3 | <25 | 15 |
| 9 | 3 | No | 4 | <25 | 31 |
| 10 | 4 | No | 3 | <25 | 10 |
| 11 | 5 | No | 4 | <25 | 31 |
| 12 | 6 | No | 2 | <25 | 15 |
| 13 | 8 | Yes | 1 | <25 | 7.4 |
| 14 | 9 | yes | 1 | <25 | 31 |
| 15 | 10 | yes | 3 | <25 | 10 |
| 16 | 8 | no | 1 | <25 | 7.4 |
| 17 | 9 | no | 1 | <25 | 31 |
| 18 | 10 | no | 3 | <25 | 10 |
| 19 | 11 | yes | 5 | 50 | 5.5 |
| 20 | 12 | yes | 4 | 100 | 15 |
| 21 | 13 | yes | 5 | 100 | 7.4 |
| 22 | 14 | yes | 2 | 50 | 21 |
| 23 | 11 | no | 5 | <25 | 5.5 |
| 24 | 12 | no | 4 | 100 | 15 |
| 25 | 13 | no | 5 | 100 | 7.4 |
| 26 | 14 | no | 2 | 50 | 21 |

### Examples 27-34

For each of Examples 27-30, Coating 1 described above was coated as an imageable layer formulation onto Substrate 1 using a slot coater then dried at approximately 82° C. for 60 seconds to obtain a dry imageable layer weight of 1.6 g/m². The topcoat formulation from TABLE II was then similarly coated on top of each imageable layer, but the total solids and application rate of the topcoat formulation was varied to produce different dry coating weights. The resulting imageable elements (printing plate precursors) were imaged, optionally post exposure baked, pre-rinsed, mounted on press, and evaluated as described for Examples 1-12. The topcoat was at least partially removed in each example. The results are given below in TABLE VII and show that a topcoat range of 0.5-1.9 g/m² will still form a clean, non-printing background while the exposed (imaged) regions print images at reasonable exposures.

TABLE VII

| | | | Number of | Lowest exposure |
|---|---|---|---|---|
| | Topcoat | Post | impressions | (μJ/cm²) showing a |
| | weight | Exposure | for a clean | completely printed |
| Example | (g/m²) | Bake? | background | solid after 200 copies |
| 27 | 0.5 | Yes | <25 | 5.5 |
| 28 | 1.0 | Yes | 50 | 5.5 |
| 29 | 1.5 | Yes | 50 | 5.5 |
| 30 | 1.9 | Yes | 50 | 5.5 |
| 31 | 0.5 | No | <25 | 5.5 |
| 32 | 1.0 | No | 50 | 5.5 |
| 33 | 1.5 | No | 50 | 5.5 |
| 34 | 1.9 | No | 50 | 5.5 |

### Comparative Example

For a Comparative Example, an imageable element was prepared and exposed as described in Example 1. A pre-rinse step was not performed before the printing plate was mounted on press and printing was begun as described for Example 1. Both imaged and non-exposed regions printed black, showing that the pre-rinse step is necessary for on-press development of the non-exposed regions.

### Example 35

An imageable layer formulation (100 g) was prepared by dissolving or dispersing 3.46 g of Hybridur® 580 polymer dispersion, 10.37 g of Copolymer 2 (10% in MEK/PGME/BLO/water at 5:2:1:1 ratio, acid number of 98 mg KOH/g), 1.57 g of SR399, 1.57 g of NK ester A-DPH, 0.31 g of Phosmer PE, 0.47 g of IB-05, 0.22 g of IRT, 0.94 g of Pigment A (27% in PGME), and 1.26 g of FluorN2900 (5% in PGME) in 23.03 g of PGME, 7.68 g of BLO, 36.86 g of MEK, 6.16 g of methanol, and 6.10 g of water. This formulation was applied to Substrate 2 to provide a dry coating weight of about 1.2 g/m².

On the resulting imageable layer, an oxygen-barrier topcoat formulation (100 g) comprising 2 g of Elvanol® 5105, 4 g of IPA, 93 g of water, and 1 g of Masurf® FS-1520 (1% in water) was applied to provide a dry coating weight of about 0.4 g/m². Both formulations were line coated using a slot coater.

The resulting imageable element (printing plate precursor) was imagewise exposed on a Kodak Trendsetter 3244 imagesetter (Eastman Kodak, Rochester, N.Y.) with an exposure series from 50 to 150 mJ/cm². After imaging, the imaged elements were passed through the pre-rinse section of a Raptor 85 plate processor (Glunz & Jensen, Denmark) containing water by which the oxygen-barrier topcoat was at least partially removed.

The resulting lithographic printing plate was mounted on-press and sheets were printed as described for Examples 1-12. The non-exposed regions (background) of the printed sheets were clean of ink by 100 impressions. After 200 impressions, the lowest exposure showing a completely printed solid was 50 mJ/cm². These results show that the method of this invention can be used to prepare a lithographic printing plate that is sensitive to and exposed in the near infrared wavelengths.

The invention has been described in detail with particular reference to certain preferred embodiments thereof, but it will be understood that variations and modifications can be effected within the spirit and scope of the invention.

1. A method of making an imaged element comprising:
A) imagewise exposing an imageable element comprising a hydrophilic support having thereon a negative-working imageable layer to form exposed and non-exposed regions in said imageable layer,
said imageable element also comprising a water-soluble topcoat disposed on said imageable layer,
B) with or without a post exposure bake step, pre-rinsing said imagewise exposed element with water or an aqueous solution to at least partially remove said water-soluble topcoat on said imagewise exposed element and incompletely or not at all, to remove said non-exposed regions of said imageable layer, and
C) after mounting it in a printing press, contacting said imagewise exposed imageable element with a fountain solution, a lithographic printing ink, or a combination of a fountain solution and a lithographic printing ink, thereby removing non-exposed regions of said imageable layer.

2. The method of claim 1 wherein said imageable element further comprises a radiation absorbing compound that is sensitive to imaging radiation.

3. The method of claim 2 wherein said imagewise exposing is carried out using imaging radiation having a λₘₐₓ of from about 150 to about 450 nm.

4. The method of claim 1 wherein said imageable layer comprises a free radically polymerizable component, a radiation absorbing compound, an initiator composition capable of generating radicals sufficient to initiate polymerization of said free radically polymerizable component upon exposure to imaging radiation, and a polymeric binder.

5. The method of claim 4 wherein said polymeric binder comprising a hydrophobic backbone and first pendant groups comprising poly(alkylene glycol) groups, and said polymeric binder optionally including second pendant groups comprising cyano groups.

6. The method of claim 5 wherein said polymeric binder comprises both said first and second pendant groups at a molar ratio of said second pendant groups to said first pendant groups of from about 14:1 to about 1000:1.

7. The method of claim 5 wherein said polymeric binder is derived from one or more of (meth)acrylonitriles and one or more poly(alkylene glycol) methyl ether (meth)acrylates, and optionally from one or more of styrene or styrene derivatives.

8. The method of claim 5 wherein said polymeric binder is present at least partially in the form of discrete particles.

9. The method of claim 1 wherein said imageable layer comprises a polymeric binder in an amount of from about 10 to about 50 weight %, a free radically polymerizable component in an amount of from about 20 to about 70 weight %, a radiation absorbing compound in an amount of from about 4 to about 20 weight %, and an initiator composition in an amount of from about 2 to about 20 weight %.

10. The method of claim 1 wherein said topcoat is an oxygen barrier comprising a water-soluble polymer.

11. The method of claim 1 wherein step B is carried out for at from about 2 to about 30 seconds at a temperature of from about 15 to about 80° C.

12. The method of claim 1 wherein in step C, said mounted imagewise exposed imageable element is contacted first with a fountain solution and then with a lithographic printing ink.

13. The method of claim 1 wherein said substrate comprises a grained and anodized aluminum support.

14. The method of claim 13 wherein said grained and anodized aluminum support has been additionally treated with poly(acrylic acid).

15. An imaged element obtained from the method of claim 1.

16. A method of making an imaged element comprising:
A) imagewise exposing an imageable element comprising a hydrophilic support having thereon a negative-working imageable layer to form exposed and non-exposed regions in said imageable layer, said imagewise exposing being carried out using imaging radiation having a λₘₐₓ of from about 300 to about 450 nm,
said imageable layer comprising a radiation absorbing compound that is a 2,4,5-triaryloxazole derivative, a free radically polymerizable component, an initiator composition that comprises a hexaarylbiimidazole, and a polymeric binder that is derived from all of (meth)acrylonitrile, styrene, and poly(ethylene glycol) methyl ether (meth)acrylate, said polymeric binder being present at least partially in the form of discrete particles,
said imageable element also comprising a water-soluble topcoat comprising poly(vinyl alcohol) that is disposed on said imageable layer,
B) with or without a post exposure bake step, pre-rinsing said imagewise exposed element with water to remove substantially all of said water-soluble topcoat,
B′) mounting said imagewise exposed imageable element in a printing press, and
C) contacting said mounted imagewise exposed imageable element with a fountain solution and then a lithographic printing ink, thereby removing the non-exposed regions of said imageable layer.

17. A method of making an imaged element comprising:
A) imagewise exposing an imageable element comprising a hydrophilic support having thereon a negative-working imageable layer to form exposed and non-exposed regions in said imageable layer,
said imageable element also comprising a water-soluble topcoat disposed on said imageable layer,
B) with or without a post exposure bake step, pre-rinsing said imagewise exposed element with water or an aqueous solution to at least partially remove said water-soluble topcoat on said imagewise exposed element and incompletely or not at all, to remove said non-exposed regions of said imageable layer, and
C) after mounting it in a printing press, contacting said imagewise exposed imageable element with a fountain solution, a lithographic printing ink, or a combination of a fountain solution and a lithographic printing ink, thereby removing non-exposed regions of said imageable layer, and
D) simultaneously with or subsequently to step C, using said mounted imagewise exposed imageable element to provide a printed image.
